(19) United States
(12) Patent Application Publication
(10) Pub. No.: US 2016/0377659 A1
(43) Pub. Date: Dec. 29, 2016

(54) FASTENING ELEMENT FOR A CURRENT SENSOR

(71) Applicant: HARTING ELECTRIC GMBH & CO. KG, Espelkamp (DE)

(72) Inventor: Andre Tiemann, Bad Essen (DE)

(73) Assignee: Harting Electric GmbH & Co., KG, Espellkamp (DE)

(21) Appl. No.: 15/111,970

(22) PCT Filed: Jan. 20, 2015
(86) PCT No.: PCT/DE2015/100026

§ 371 Date: Jul. 15, 2016

(30) Foreign Application Priority Data
Mar. 3, 2014 (DE) 10 2014 102 793.0

(51) Int. Cl. G01R 15/18; G01R 19/00; F16B 21/07

(52) U.S. Cl. CPC G01R 15/18; F16B 21/071; F16B 21/073; G01R 19/0092

(57) ABSTRACT

The object of the present invention is to reduce the manual assembly effort of current sensors, and to specify a configuration for a fastening element (1) by means of which a current sensor (2) can be fastened on a fastening surface (3) in both lying and standing positions with the lowest possible effort. The Listening element (1) according to the invention therefore proposes at least one, preferably two, snap-in locking devices and can thus be Listened (“clipped”) on to the current sensor with the lowest possible manual effort. For example, two fastening elements (1, 1′) according to the invention, with the snap-in locking devices on opposite sides, can be inserted into the same screw passages (23, 24) of the current sensor (2) and, in particular, lock each other in place using the snap-in locking devices in a screw hole (231, 241) belonging to the respective screw passage (23, 24) and thus are held on the current sensor (2).

The invention relates to a fastening element for a current sensor in accordance with the preamble of independent claim 1.

Fastening elements of this type are required in order to be able to fasten a current sensor not only in a manner where said sensor lies flat but rather alternatively also where said sensor stands on a fastening surface.

### PRIOR ART

EP 1 181 698 1 B1 discloses a current sensor having two assembly positions that can be fastened in such a manner that said sensor is either standing upright or lying flat on a supporting surface. This current sensor comprises a housing that comprises a first set of feedthroughs for fastening screws whose axes lie perpendicular with respect to a large surface of the housing for fastening said current sensor in a flat-lying state on the support surface, wherein a second set of feedthroughs is provided for fastening screws whose axes lie perpendicular with respect to that of the first set of screw feedthroughs for fastening the housing in an upright state on the support surface, characterized in that said current sensor additionally comprises at least one flange-mounting auxiliary element that is allocated to the housing and is joined to said housing in a form-complementing manner solely for fastening the housing in an upright state on the support surface and the second set of screw feedthroughs is embodied in said housing.

In particular, this publication discloses an arrangement in which two flange-mounting auxiliary elements are fastened to one another and consequently to the housing by means of a total of 4 screws through screw feedthroughs of the housing. Furthermore, these two flange-mounting auxiliary elements can be screwed on the support surface at a right angle with respect to the support surface by means of a total of four further screws so that in the case of this embodiment a total of eight screws are required and must be screwed in in order to fasten a single current sensor.

Furthermore, by way of example the registered design DM/062779 discloses a design for a current sensor that also comprises two smaller fastening elements. These two fastening elements are clearly provided for the purpose of being fastened to the current sensor lying opposite one another by means of a total of two screws.

In the case of known arrangements of this type, it is necessary to guide at least two screws from one side through these fastening elements and through screw feedthroughs of the current sensor housing and to screw said screws from the other side, by way of example such that the screw feedthroughs of the mating side comprise corresponding screwing bore holes having an inner thread or by means of the use of corresponding lock nuts, wherein the lock nuts can be advantageously inserted in each case in one of the screw feedthroughs. This procedure of inserting the lock nuts is obviously used to make the entire arrangement compact but requires where necessary a specific manual effort during the assembly process. Furthermore, in the case of a screw connection of this type, there is fundamentally the danger that the screws can also become detached as a result of prolonged vibrations, such as occur for example in rail operation. This can be counteracted clearly by means of further means such as for example the use of specially formed washers, which however means an additional assembly expenditure.

One disadvantage in the case of this prior art is therefore inter alia the relatively high manual effort during the assembly process.

### OBJECT OF THE INVENTION

The object of the invention resides in reducing this expenditure and providing a construction for a fastening element with which it is possible to fasten a corresponding current sensor with as little expenditure as possible not only in a manner where said sensor is fastened in a flat-lying state but also where said sensor is fastened in an upright state on a fastening surface.

The object is achieved by means of a fastening element of the type mentioned in the introduction by means of the features of the characterizing part of independent claim 1.

A fundamental advantage of the invention resides in the fact that the fastening element comprises at least one, preferably two, latching devices and consequently can be fastened (clipped) to the current sensor with as little manual effort as possible. By way of example, two fastening elements in accordance with the invention with their latching devices of opposite-lying sides can be plugged into the same screw feedthroughs of the current sensor and in particular can latch to one another in a screw bore hole that is associated with the respective screw feedthrough and thus be held on the current sensor.

As could be demonstrated by means of complex testing runs, an additional advantage of the invention resides in the fact that vibrations, such as those that by way of example occur in the case of rail operation, do not cause irreversible alterations to this latching state, whereby the vibrations can in other words also act upon the fastening element for a long period of time without consequently impairing the latching state of the fastening element.

A further additional advantage resides in the fact that the current sensor can be fastened to the fastening surface in different orientations with only little effort. In particular, the current sensor can be arranged with its contact connector side, in other words with the side at which its electrical connectors are arranged or the side that is at least suitable for the purpose of arranging these electrical connectors, at a right angle with respect to the fastening surface. The current sensor can however also be aligned in such a manner that its contact connecting side is aligned parallel with respect to the fastening surface and is remote from said fastening surface. As a consequence, in order to measure the current of a current rail that extends parallel to the fastening surface and naturally through the core hole of the current sensor, the current sensor can assume three different orientations for the alignment of the contact connecting side, wherein the variants that in each case occur by means of a 180° rotation about an axis that extends perpendicular with respect to the fastening plane, are not taken into account.

Advantageous embodiments of the invention are disclosed in the dependent claims.

In a preferred embodiment, the latching devices of the fastening element are on the one hand a latching spigot and on the other hand an arrangement of multiple, preferably two or three, latching limbs. The latching spigot and the arrangement of multiple latching limbs preferably comprise a mutually latchable form. This has the advantage that two identical fastening elements are able to latch to one another in that in each case a latching spigot of the one fastening element latches on the latching limbs of the in each case other fastening element.

It is furthermore advantageous for fastening the current sensor to the fastening surface if the fastening element that is preferably embodied as a single part comprises on one hand at least one flange region and on the other hand at least one latching device, preferably two latching devices.

The flange region can comprise a base region for fastening to the fastening surface. This base region can comprise by way of example a base strip and can furthermore comprise at least one, preferably two, base surfaces. As a consequence, a large mechanical contact surface with the fastening surface is ensured, which benefits the stability of the fastening arrangement. It is possible to arrange a fastening slot in each of the base surfaces by way of example for screwing or fastening in another manner to the fastening surface.

Advantageously, the flange region comprises at least one clamping surface. The base strip, the base surfaces and the clamping surface can adjoin one another and in addition can be connected to one another by way of stabilizing means, by way of example at least one stabilizing surface, so as to stabilize their mutual fastening arrangement. By way of example, in each case one of the two base surfaces having the clamping surface can connect in each case two stabilizing surfaces and preferably extend in a perpendicular manner both with respect to the base surface as well as with respect to the clamping surface, whereby a particularly good stability of the flange region is ensured.

The base surfaces and the base strip of the respective fastening element preferably lie in a first plane. Between this first plane and a second plane in which the clamping surface lies there is an angle α that is by way of example between 88° and 94°, advantageously however between 90° and 92°. Consequently, the angle α by way of example can be a right angle. However, it is particularly advantageous for fastening the current sensor in a stable manner if the angle α is slightly greater than 90°. It is preferred that the angle α is greater than 90.25°. It is particularly preferred that the angle α is greater than 90.5°. In particular, the angle α can be greater than 90.75°, in other words for example 91° or more.

In particular, the respective latching device can comprise a first holding arm and the latching spigot that is formed on said first holding arm, and also a second holding arm and latching limbs that are formed on said second holding arm.

The latching spigot can comprise an axis of symmetry along its extent and is preferably constructed at least in a mirror-symmetrical manner with respect to said axis of symmetry. Consequently, the width of said latching spigot can vary at least in a specific direction along this axis of symmetry. This renders it possible that at least in this direction the latching spigot either tapers, in other words forms a latching recess, and/or widens, wherein the two variants of the latching arrangement, by way of example between the latching limbs of a further, identical fastening element, can be used. In particular, the latching spigot can comprise a tapering by means of two latching recesses that lie opposite one another. Furthermore, an embodiment is also feasible in which the latching spigot is constructed in such a manner that it tapers and/or widens even in a rotationally symmetrical manner.

Multiple, preferably two, possibly however also three or more, latching limbs are arranged on the second holding arm. It is possible by means of these latching limbs to form a hollow space that is open towards its free-standing end and is tapered in a conical manner.

The latching limbs comprise latching lugs on their ends. Latching lugs can be moldings, and/or the latching lugs can by way of example also be formed by virtue of the fact that the latching limbs are accordingly curved towards one another and extend towards their open end towards one another.

These latching lugs are by way of example suitable for the purpose of engaging into the latching recesses of the latching spigot in order to latch to this.

Two such, in particular identical, fastening elements can be fastened to a current sensor lying opposite one another by means of a mating-side latching arrangement in order to in turn fasten these to the fastening surface. The current sensor preferably comprises four screw feedthroughs, wherein a screw bore hole is arranged in each of the screw feedthroughs and in particular at least three holding elements can be arranged around each of these screw bore holes. In particular, these holding elements can be essentially cuboid holding strips that advantageously comprise identical spacing with respect to the screw bore hole and ideally are arranged in equidistant angular spacings around the screw bore hole. It is also possible by means of these holding elements, in particular these holding braces, for the holding arms of the fastening elements to be held in the screw feedthroughs.

The two holding elements can be fixed to the current sensor by virtue of the fact that said holding elements latch to one another with their latching spigots and latching limbs in the screw bore holes.

As is mentioned above, it is advantageous if the angle a is slightly greater than 90° because two fastening elements that have been attached (clipped) to the current sensor and lie opposite one another are screwed with their base surfaces to a fastening surface then their clamping surfaces are pressed from both sides against the current sensor and the current sensor is thus clamped between these two fastening elements.

The latching devices are simultaneously arranged in the screw feedthroughs of the current sensor. In particular, the latching spigots and latching limbs in the screw bore hole press the current sensor in the direction of the fastening surface and thus ensure additional stability. Furthermore, it is also advantageous in this respect if the latching devices of the fastening element in each case comprise a holding arm. Finally, this holding arm is located in the respective screw feedthrough of the current sensor and is by its holding elements, in particular holding braces, and can press the current sensor at this site additionally against the fastening surface.

### EXEMPLARY EMBODIMENT

An exemplary embodiment of the invention is illustrated in the drawings and is further explained hereinunder. In the drawings:

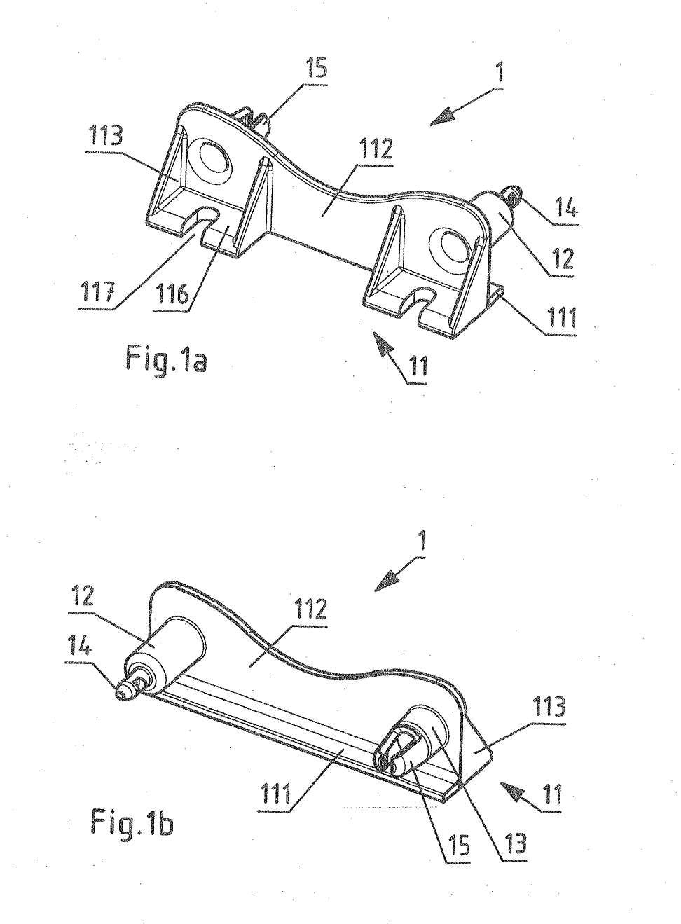

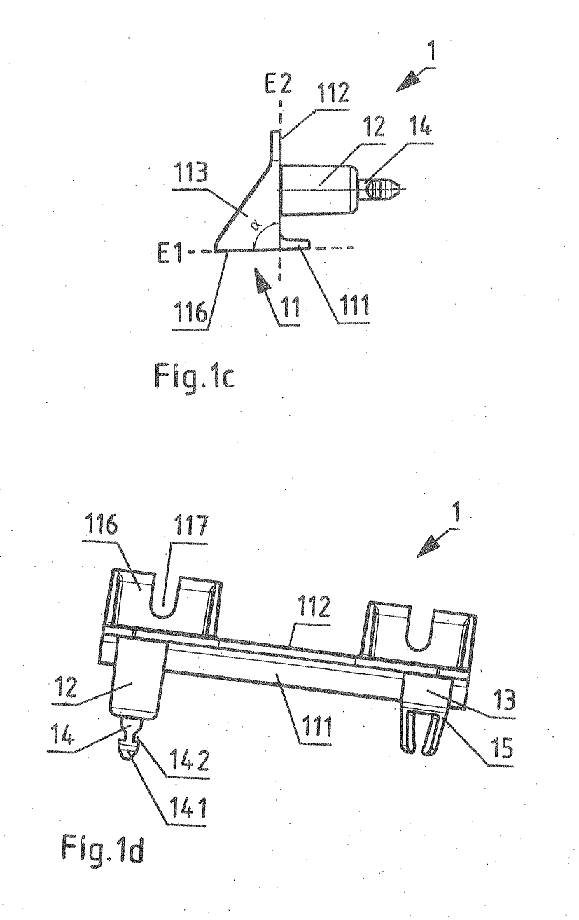

FIG. 1a illustrates a fastening element in an oblique view from above (flange region side),

FIG. 1b illustrates the fastening element in an oblique view from above (plug side),

FIG. 1c illustrates the fastening element from the side,

FIG. 1d illustrates the fastening element from above,

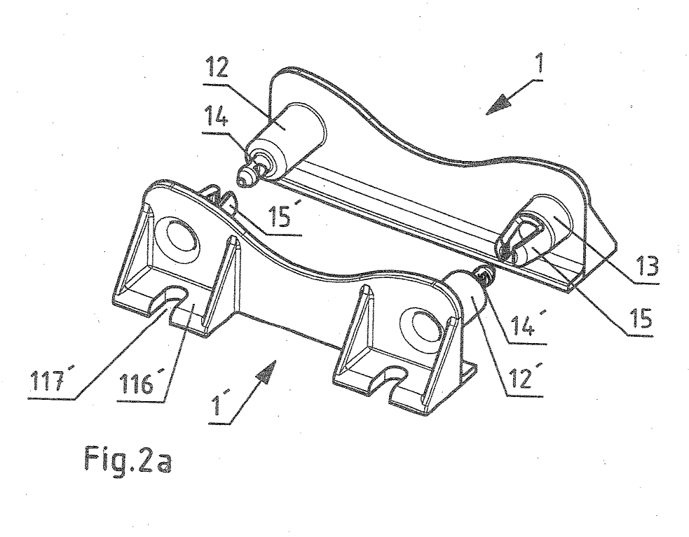

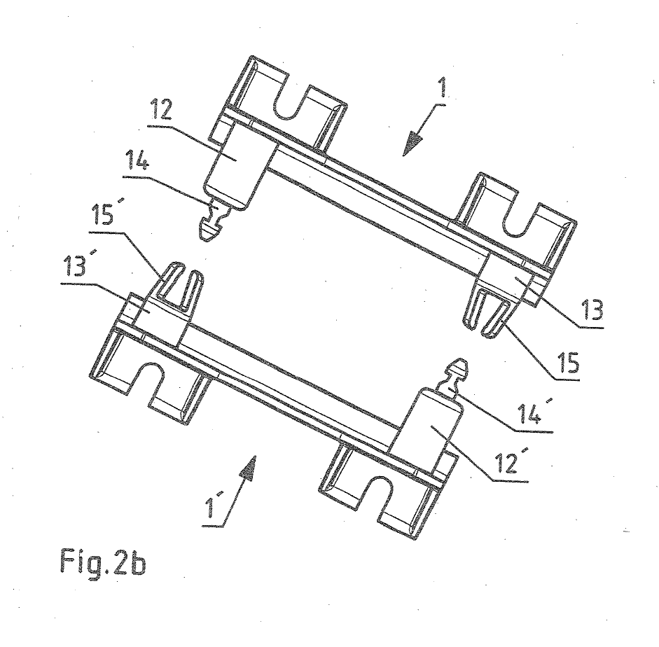

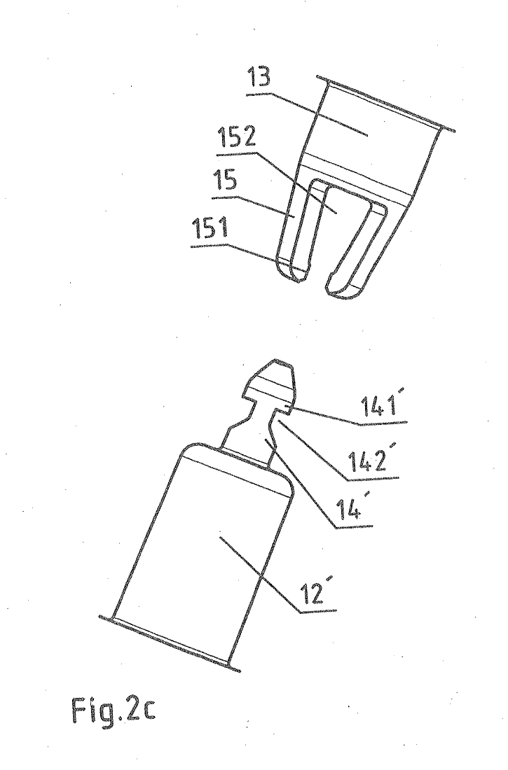

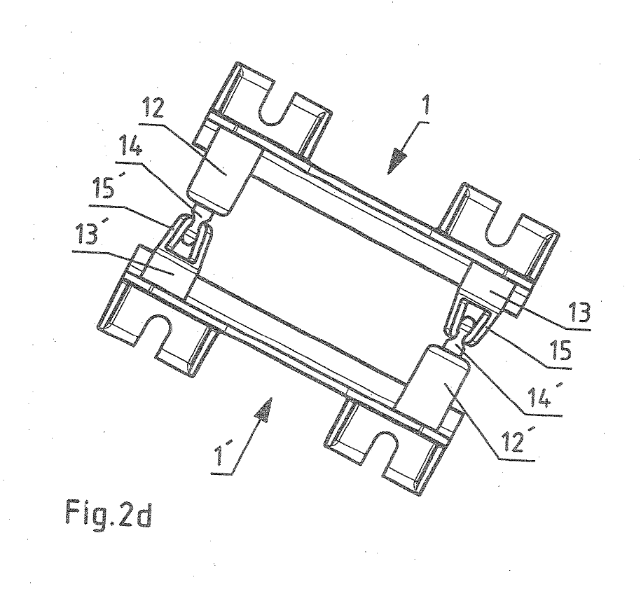

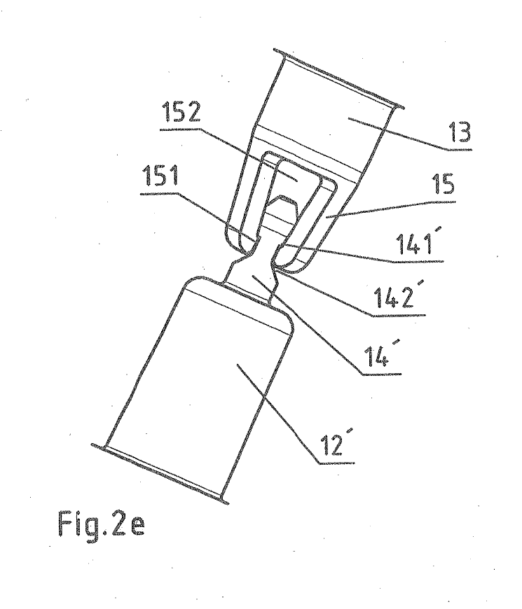

FIG. 2a illustrates two fastening elements in an unlatched state in an oblique view from above,

FIG. 2b illustrates two fastening elements in an unlatched state from above,

FIG. 2c illustrates a latching spigot and a latching recess in an unlatched state in an enlarged view,

FIG. 2d illustrates from above the two fastening elements that are latched to one another,

FIG. 2e illustrates in an enlarged view the latching recess and the latching spigot that is latched in said latching recess,

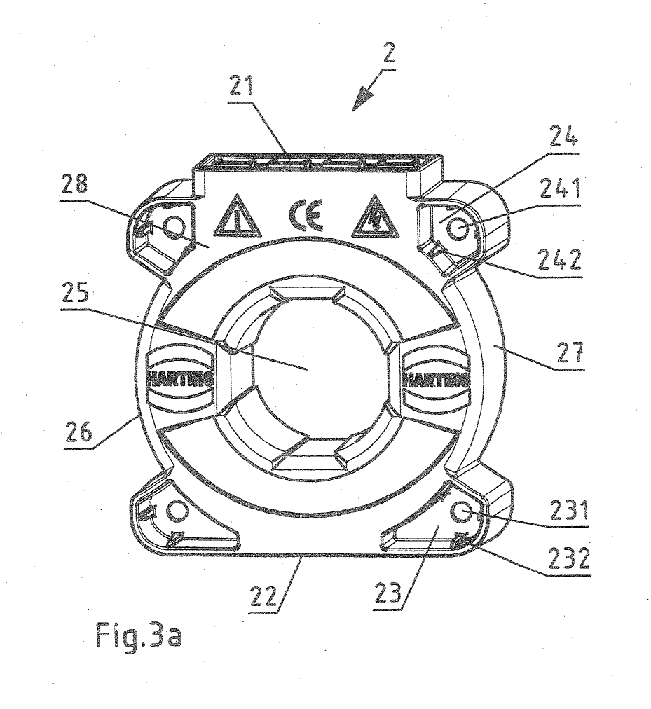

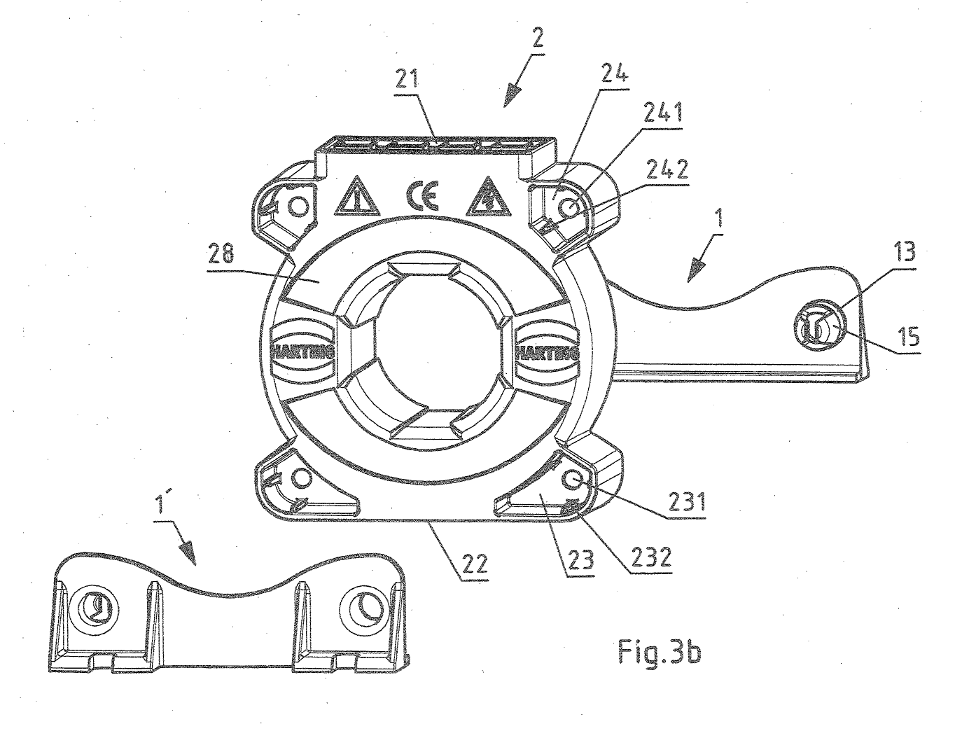

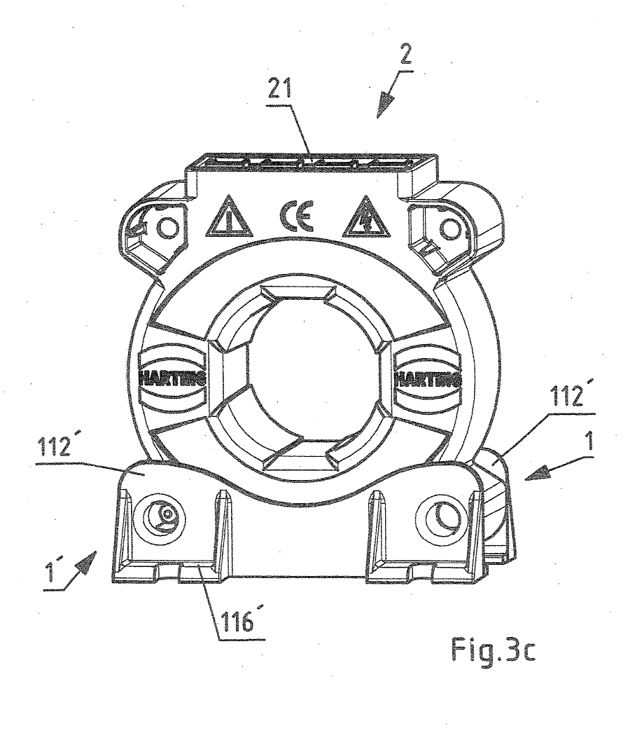

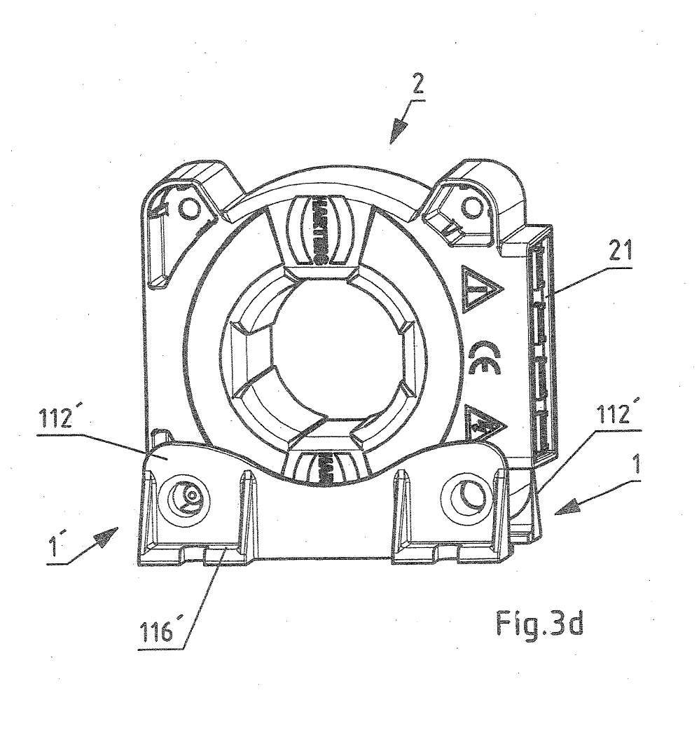

FIG. 3a illustrates a current sensor that is to be fastened,

FIG. 3b illustrates the current sensor having two unlatched fastening elements,

FIG. 3c illustrates the current sensor having two fastening elements that are fastened and latched to said current sensor,

FIG. 3d illustrates the current sensor having two fastening elements that are fastened and latched to said current sensor in a second orientation,

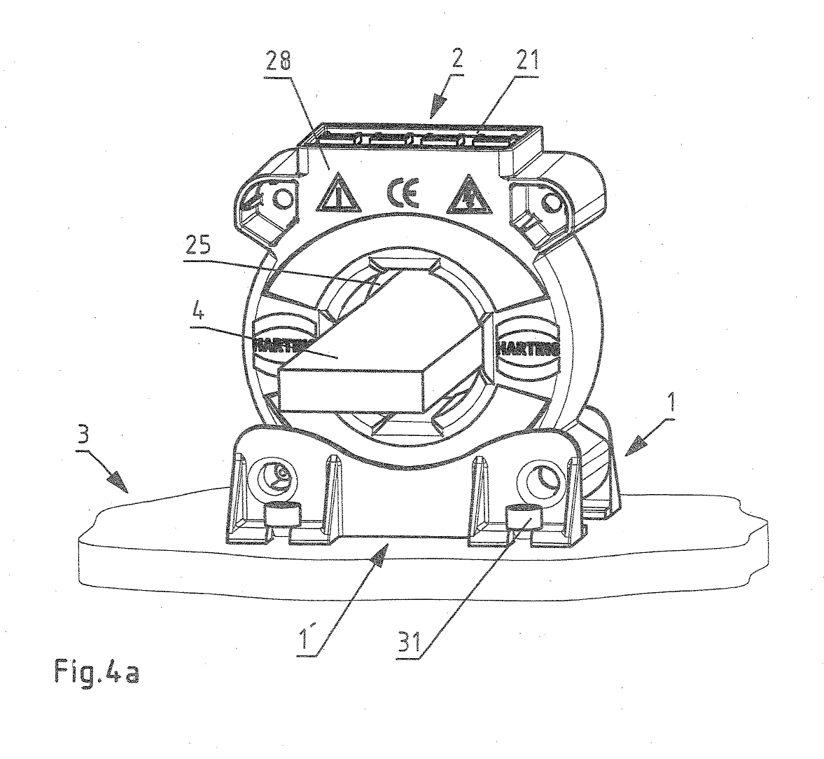

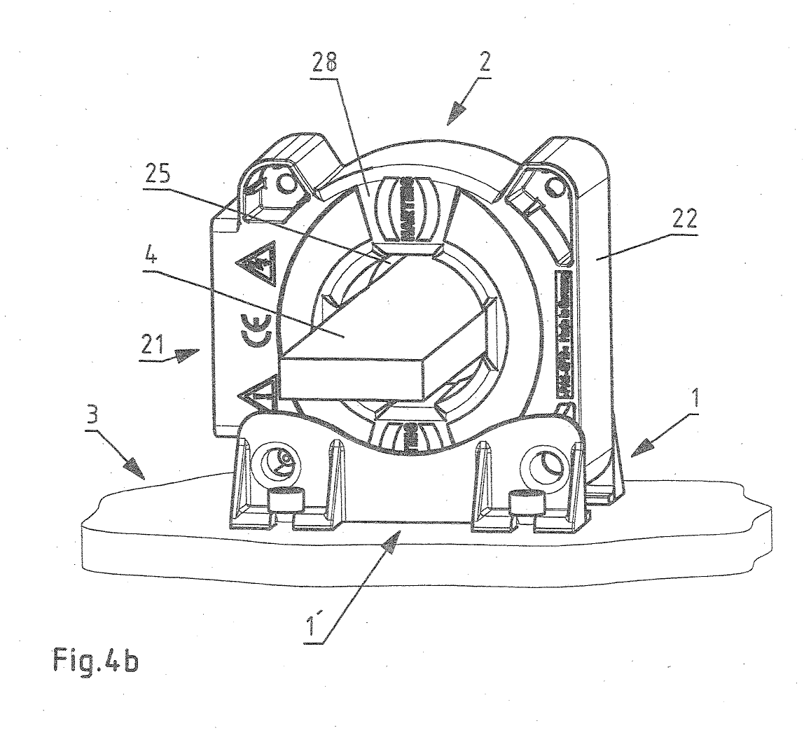

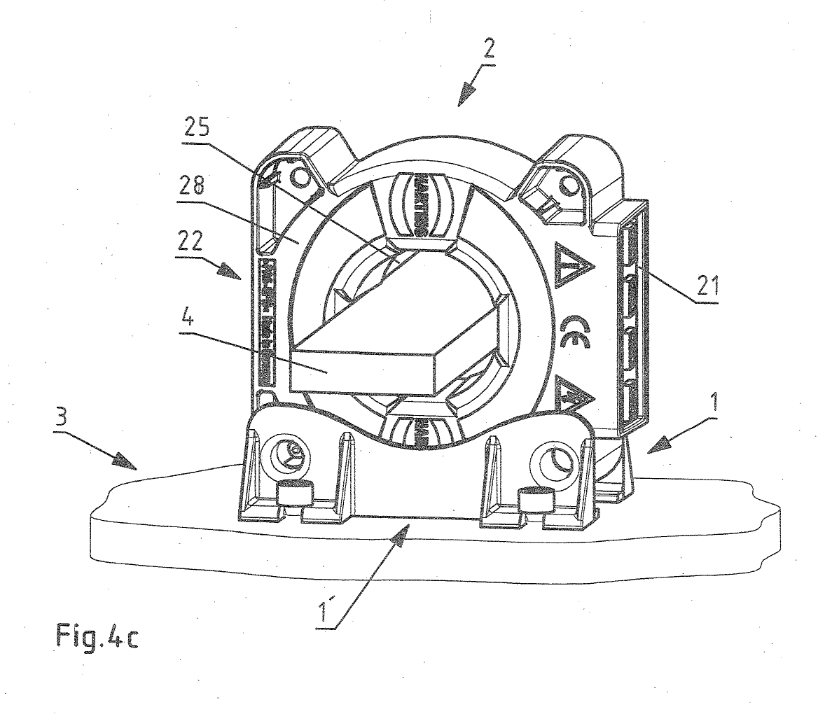

FIG. 4a, b, c illustrates the current sensor having two fastening elements on a fastening surface having a current rail.

The FIGS. 1a, b, c and d illustrate a fastening element 1 in various views. This fastening element comprises a flange region 11 and two latching devices, namely a first latching device and a second latching device.

The flange region 11 is particularly visible in FIG. 1. The flange region comprises a base region for fastening to a fastening surface 3. This base region comprises a base strip 111 that is in turn particularly visible in FIG. 1b, and two base surfaces 116. In each of these base surfaces 116, it is possible to arrange a fastening slot 117, by way of example for screwing or otherwise fastening to the fastening surface 3. Advantageously, the flange region 11 comprises a clamping surface 112. The base strip 111, the two base surfaces 116 and the clamping surface 112 adjoin one another and are in addition connected to one another by way of stabilizing surfaces 113 so as to stabilize their mating-side fastening. Each of the two base surfaces 16 is connected to the clamping surface 112 by way of in each case two stabilizing surfaces 113. The stabilizing surfaces preferably both extend perpendicular with respect to the base surfaces 116 as well as with respect to the clamping surface 112, whereby particularly great stability is ensured.

As is evident in FIG. 1c, the base surfaces 116 and the base strip 111 of the respective fastening element 1 lie in a first plane E1. There is an angle α, which can advantageously be between 90° and 92°, between this first plane E1 and a second plane E2 in which the clamping surface lies. Consequently, the angle α can be by way of example a right angle. However, it is advantageous for fastening the current sensor in a stable manner if the angle α is slightly greater than 90°. It is preferred that the angle α is greater than 90.25°. It is particularly preferred that the angle α is greater than 90.5°. In particular, the angle α can be greater than 90.75°, in other words for example 91° or more.

The first latching device comprises a first holding arm 12 and the latching spigot 14 that is formed on said holding arm. The second latching device comprises a second holding arm 13 and latching limbs 15 that are formed on said second holding arm.

The latching spigot 14 comprises along its extent an axis of symmetry and said latching spigot is constructed in an essentially mirror-symmetrical manner with respect to said axis. The width of the latching spigot 14 tapers along this axis of symmetry in a specific direction, whereby a latching recess 142 is formed on the two sides of the latching spigot 14.

Two latching limbs 15 are arranged on the second holding arm 13. A hollow space is formed by means of these latching limbs 15 and said hollow space tapers in a conical manner and is open towards the free-standing ends of said latching limbs. The latching limbs 15 comprise latching lugs 151 on their ends that are particularly evident in FIG. 1d. The latching lugs 151 can also be moldings, and/or the latching lugs 151 can also be embodied by way of example by virtue of the fact that the latching limbs 15 are accordingly curved towards one another and extend towards one another towards their open ends.

These latching lugs 151 are suitable for the purpose of engaging in the latching recesses 142 of the latching hook 14 in order to latch said latching hook.

FIGS. 2a, b, c, d, e illustrate two such opposite-lying fastening elements 1, 1′ in the unlatched or in the latched state.

FIG. 2a illustrates the two fastening elements 1, 1′ in a 3D illustration, wherein it is clear that the respective latching hook 14, 14′ is provided for the purpose of latching between the latching limbs 15′, 15 of the in each case other fastening element 1, 1′.

FIGS. 2b and 2c illustrate the two fastening elements 1, 1′ in the unlatched state in an oblique view from above. In particular, FIG. 1c clearly illustrates the manner in which the latching spigot 14′ that is formed on the first holding arm 12′ and comprises its two latching recesses 142′ and the latching hook 141′ that is formed as a result is able to latch on the latching limbs 15 having their latching lug 151. The latching limbs 15 are formed on the second holding arm 13 and form a hollow space 152 that extends in a conical manner towards its free-standing ends.

FIGS. 2d and 2e illustrate the two fastening elements 1, 1′ in a latched state. In particular, FIG. 2e clearly illustrates the manner in which the latching spigot 14′ is inserted into the hollow space 152 and the manner in which the latching lugs 151 of the latching limbs 15 engage in the latching recesses 142′ on the two sides of the latching spigot 14′ in order to latch the latching hook 141′ of said latching spigot in the hollow space 152.

FIG. 3a illustrates a corresponding current sensor 2 having a contact connecting side 21 and a second side 22 that lies opposite said contact connecting side, and also a third side 26 and a fourth side 27. At a right angle to this, the current sensor naturally comprises a front side 28 that is visible in the drawing and a rear side that is concealed in the drawing. The current sensor comprises a central core hole 25 that is provided by way of example for attaching the current sensor to the current rail. The current sensor 2 comprises on its corners four screw feedthroughs 23, 24, wherein a screw bore hole 231, 241 is arranged in each of the screw feedthroughs 23, 24 and in particular around each of these screw bore holes, three cuboid holding braces 232, 242 are arranged that advantageously comprise the identical spacing with respect to the respective screw bore hole 231, 241 and ideally are arranged around the screw bore hole 231, 241 in equidistant angular spacings. The holding arms of the fastening elements can be held in the screw feedthroughs 23, 24 by means of these holding braces 232, 242.

FIG. 3b illustrates the current sensor 2 having the two fastening elements 1, 1′ that are latched to said current sensor.

In FIG. 3c, the two holding elements 1, 1′ are fixed to the current sensor 2 by virtue of the fact that they latch to one another with their latching devices in the screw feedthroughs 23 that are located on the planar side 22. The current sensor 2 is also fastened to the fastening surface 3 by means of screwing the base surface 116 of the fastening elements 1, 1′ to the fastening surface 3.

As is mentioned above, it is advantageous if the angle α that is illustrated in FIG. 1c is slightly greater than 90°. If the two base elements 1, 1′ are screwed to their fastening surfaces 116, 116′ on a planar fastening surface 3, then their clamping surfaces 112, 112′ are pressed from the two sides against the current sensor 2 and the current sensor 2 is thus clamped between these two fastening elements 1, 1′.

The latching devices of the two fastening elements 1, 1′ are simultaneously arranged in the screw feedthroughs 23 of the current sensor. The latching spigots 14, 14′ and latching limbs 15, 15′ in the screw bore holes 23, 24 press the current sensor 2 in the direction of the fastening surface 3 and thus ensure additional stability. Furthermore, the respective holding arm 12, 12′, 13, 13′ can be held in the respective screw feedthrough 23 by the holding braces 232 and then presses the current sensor 2 additionally against the fastening surface 3.

FIG. 3c illustrates a comparable arrangement but in this case the two holding elements are inserted by means of in each one latching device in a screw feedthrough 23 that is located on the planar side 22 of the current sensor 2, and are inserted by means of the respective other latching device in a screw feedthrough that is located on the contact side 21 of the current sensor 2. In this manner, the current sensor 2 can be fastened in various orientations to the fastening surface 3.

FIGS. 4a, b, c illustrate the various possible orientations of the current sensor that is fastened to the fastening surface 3. The fastening elements 1, 1′ that are latched to one another as embodied in the current sensor are screwed to the fastening surface 3 with their base surfaces by means of fastening screws 31. As a consequence, the current sensor 2 can be clamped between its clamping surfaces 112, 112′.

As described above, the latching devices are simultaneously arranged in the screw feedthroughs 23, 24 of the current sensor 2. The latching spigots 14, 14′ and latching limbs 15, 15′ in the screw bore holes 231, 241 press the current sensor 2 in the direction of the fastening surface 3 and thus ensure additional stability. Furthermore, the respective holding arm 12, 12′, 13, 13′ is held in the respective screw feedthrough 23, 24 by the associated holding braces 232, 242 and presses the current sensor 2 additionally against the fastening surface 3.

Furthermore, a current rail 4 is illustrated, said current rail extending parallel to the fastening surface 3 that extends through the core hole 25 of the current sensor 2 and at a right angle with respect to its front side 28.

FIG. 4a illustrates the current sensor that is attached at its planar side 22 to the two fastening elements 1, 1′ on the fastening surface 3 so that its contact connecting side 21 is aligned parallel to the fastening surface 3 and aligned remote from said fastening surface.

FIGS. 4b and 4c illustrate the current sensor that is attached on its third side 26 or rather with its fourth side 27 having the two fastening elements 1, 1′ to the fastening surface 3 in such a manner that its contact connecting side 21 is aligned in each case at a right angle with respect to the fastening surface 3.

### LIST OF REFERENCE NUMERALS

1, 1′ Fastening element
11, 11′ Flange region
111 Base strip
112, 112′ Clamping surface
113 Stabilizing surface
116, 116′ Base surface
117, 117′ Fastening slot
12, 12′ First holding arm
13, 13′ Second holding arm
14, 14′ Latching spigot
141, 141′ Latching hook
142, 142′ Latching recess
15, 15′ Latching limb
151 Latching lug
152 Hollow space
2 Current sensor
21 Contact connecting side
22 Second side
23, 24 Screw feedthroughs
231, 241 Screw bore hole
232, 242 Holding braces
25 Core hole
26, 27 Third, fourth side
28 Front side
3 Fastening surface
31 Fastening screw
4 Current rail
E1, E2 First, second plane

1-22. (canceled)

23. A fastening element having a flange region for fastening a current sensor in an upright state on a fastening surface wherein the fastening element comprises at least one latching device.

24. The fastening element in accordance with claim 23, wherein the fastening element comprises two latching devices, namely a first latching device and a second latching device.

25. The fastening element in accordance with claim 24, wherein at least the first latching device comprises a first holding arm and a latching spigot that is formed on said holding arm.

26. The fastening element in accordance with claim 25, wherein the latching spigot comprises at least one latching recess.

27. The fastening element in accordance with claim 26, wherein the latching spigot comprises two latching recesses that lie opposite one another.

28. The fastening element in accordance with claim 24, wherein at least the second latching device comprises a second holding arm and multiple latching limbs that are formed on said second holding arm.

29. The fastening element in accordance with claim 28, wherein the latching limbs are embodied in a resilient elastic manner.

30. The fastening element in accordance with claim 25, wherein the one or multiple holding arms are embodied in an essentially cylindrical manner.

31. The fastening element in accordance with claim 28, wherein a hollow space is formed by the latching limbs.

32. The fastening element in accordance with claim 29, wherein the latching limbs comprise latching lugs on their free-standing ends.

33. The fastening element in accordance with claim 23, wherein the flange region of the fastening element comprises at least one base surface and/or a base strip that lie in a first plane (E1), and wherein the fastening element furthermore comprises a clamping surface on which the at least one latching device is formed, wherein the clamping surface lies in a second plane (E2) and wherein the two planes (E1, E2) comprise a common angle of intersection (α).

34. The fastening element in accordance with claim 33, wherein the common angle of intersection (α) is greater than or equal to 90°.

35. The fastening element in accordance with claim 33, wherein the common angle of intersection (α) is greater than 90.25°.

36. The fastening element in accordance with claim 33, wherein the common angle of intersection (α) is greater than 90.5°.

37. An arrangement comprising a current sensor and two fastening elements in accordance with claim 23.

38. The arrangement in accordance with claim 37, wherein the current sensor comprises four screw feedthroughs.

39. The arrangement in accordance with claim 37, wherein a screw bore hole is arranged in each of the screw feedthroughs and that at least three holding elements are arranged around this screw bore hole.

40. The arrangement in accordance with claim 39, wherein the holding elements are essentially cuboid holding braces that all comprise identical spacing with respect to the screw bore hole.

41. The arrangement in accordance with claim 39, wherein the holding elements are arranged in equidistant angular spacings around the screw bore hole.

42. The arrangement in accordance with claim 38, wherein the two fastening elements are fastened to the current sensor.

43. The arrangement in accordance with claim 42, wherein the two fastening elements are fastened to the current sensor by virtue of the fact that they latch to one another with their first and second latching devices in two screw feedthroughs of the current sensor.

44. The arrangement in accordance with claim 43, wherein the screw feedthroughs to which the fastening elements are fastened are in each case two screw feedthroughs that are arranged either on a second side of the current sensor or that are screw feedthroughs that are arranged on a third side or on a fourth side of the current sensor so that a contact connecting side of the current sensor can be selectively aligned in three various directions with respect to a predetermined surface and a predetermined current rail.
